(19) United States
(12) Patent Application Publication
(10) Pub. No.: US 2012/0292681 A1
(43) Pub. Date: Nov. 22, 2012

(54) SEMICONDUCTOR DEVICE

(75) Inventors: Yoshinori IKEBUCHI, Tokyo (JP); Yoshihiro TAKAISHI, Tokyo (JP)

(73) Assignee: Elpida Memory, Inc.

(21) Appl. No.: 13/473,153

(22) Filed: May 16, 2012

(30) Foreign Application Priority Data
May 20, 2011 (JP) 2011-113175

(51) Int. Cl. H01L 29/78; H01L 29/94

(52) U.S. Cl. 257/302; 257/330; 257/E29.262; 257/E29.342

(57) ABSTRACT

A semiconductor device includes a substrate having a groove in a periphery, a gate electrode partially embedded in the groove to sandwich the substrate from opposite directions by side walls of the groove, and a diffusion layer formed over the substrate and surrounded by the gate electrode. A resistance value of the diffusion layer is changed by changing a potential between the gate electrode and the diffusion layer.

This application is based upon and claims the benefit of priority from Japanese patent application No. 2011-113175, filed on May 20, 2011, the disclosure of which is incorporated herein in its entirety by reference.

### BACKGROUND OF THE INVENTION

This invention relates to a semiconductor device, and in particular to a semiconductor device having a double-gate structure.

With recent miniaturization of resistance elements in semiconductor devices, variation in resistance value caused by processing variation has become non-negligible.

As one of related art techniques addressing this problem, a semiconductor device is proposed which has a diffused resistance element formed in a SOI layer of a SOI substrate in order to reduce the effect of junction leakage (see Japanese Laid-Open Patent Publication No. 2007-242660 (hereafter referred to as Patent Document 1)).

More specifically, Patent Document 1 discloses a resistance element having, as a resistor, an N—Si body region with N+ diffused regions at opposite ends thereof. A gate oxide film and a gate electrode are layered on top of the N—Si body region, and the resistance value of the body resistance is made variable according to a gate voltage.

However, the semiconductor device disclosed in Patent Document 1 is a semiconductor device having a single-gate structure, and no consideration is given to variation in resistance value caused by processing variation in a semiconductor device having a double-gate structure. The term “double-gate structure” as used herein refers to a structure in which a diffusion layer is sandwiched between two gates.

Further, in the semiconductor device of Patent Document 1, the gate electrode is formed on top of the N—Si body region. Therefore, this technique is not applicable to a structure in which a part of the gate electrode is embedded in a groove of a substrate (silicon beam) having a groove in a periphery thereof.

### SUMMARY

In one embodiment, there is provided a semiconductor device, comprising:

a substrate having a groove in a periphery;

a gate electrode partially embedded in the groove to sandwich the substrate from opposite directions by side walls of the groove; and

a diffusion layer formed over the substrate and surrounded by the gate electrode;

wherein a resistance value of the diffusion layer is changed by changing a potential between the gate electrode and the diffusion layer.

In another embodiment, there is provided a semiconductor device, comprising:

a substrate having a groove in a periphery;

a gate electrode partially embedded in the groove to sandwich the substrate from opposite directions by side walls of the groove; and

a diffusion layer formed over the substrate and surrounded by the gate electrode;

wherein:

a resistance value of the diffusion layer is changed by changing a potential between the gate electrode and the diffusion layer,

the resistance value of the diffusion layer is changed depending upon a cross-sectional area of the diffusion layer, the cross-sectional area being changed in accordance with a thickness of a depletion layer formed between the substrate and the diffusion layer, and

the semiconductor device is provided together with a vertical transistor.

In further other embodiment, there is provided a semiconductor device, comprising:

a semiconductor substrate including a groove which is defined by a first side surface, a second side surface, a third side surface, and a fourth side surface, the first and second side surface being faced to each other, the third and fourth side surface being faced to each other;

a gate electrode formed in the groove and having a first portion to be in contact with the first side surface and a second portion to be in contact with second side surface;

a slit provided between the first and second portions of the gate electrode;

a first diffusion layer formed in the slit and including a first end portion and a second end portion;

a second diffusion layer formed on the first end portion of the first diffusion layer;

a third diffusion layer formed on the second end portion of the first diffusion layer;

a first plug contact formed on the second diffusion layer; and

a second plug contact formed on the third diffusion layer.

### BRIEF DESCRIPTION OF THE DRAWINGS

The above features and advantages of the present invention will be more apparent from the following description of certain preferred embodiments taken in conjunction with the accompanying drawings, in which

FIG. 1 is a diagram for explaining a structure of a semiconductor device (N-type variable resistance element) according to a first embodiment of this invention, being a perspective view of the semiconductor device;

FIG. 2 is a plan view for explaining the structure of the semiconductor device according to the first embodiment of the invention;

FIG. 3 is a diagram for explaining the structure of the semiconductor device according to the first embodiment of the invention, being a cross-sectional view taken along the dotted line A in FIG. 2;

FIGS. 4A to 4C are diagrams for explaining the structure of the semiconductor device according to the first embodiment of the invention, being cross-sectional views taken along the dotted line B in FIG. 2;

FIGS. 5A to 5C are diagrams showing a step of a manufacturing method of the semiconductor device according to the first embodiment of the invention;

FIG. 6 is a diagram showing a step of the manufacturing method of the semiconductor device according to the first embodiment of the invention;

FIG. 7 is a diagram showing a step of the manufacturing method of the semiconductor device according to the first embodiment of the invention;

FIG. 8 is a diagram showing a step of the manufacturing method of the semiconductor device according to the first embodiment of the invention;

FIG. 9 is a diagram showing a step of the manufacturing method of the semiconductor device according to the first embodiment of the invention;

FIG. 10 is a plan view for explaining a structure of a semiconductor device according to a second embodiment of the invention;

FIG. 11 is a diagram for explaining the structure of the semiconductor device according to a second embodiment of the invention, being a cross-sectional view taken along the dotted line A in FIG. 10;

FIGS. 12A to 12C are diagrams for explaining the structure of the semiconductor device according to a second embodiment of the invention, being cross-sectional views taken along the dotted line B in FIG. 10;

FIG. 13 is a diagram for explaining a structure of a semiconductor device (N-type variable resistance element) according to a third embodiment of this invention, being a perspective view of the semiconductor device;

FIG. 14 is a plan view for explaining the structure of the semiconductor device according to the third embodiment of the invention;

FIG. 15 is a diagram for explaining the structure of the semiconductor device according to the third embodiment of the invention, being a cross-sectional view taken along the dotted line B in FIG. 14;

FIGS. 16A to 16C are diagrams for explaining the structure of the semiconductor device according to the third embodiment of the invention, being cross-sectional views taken along the dotted line C in FIG. 14;

FIG. 17 is a diagram for explaining a structure of a vertical transistor formed at the same time with the semiconductor device (N-type variable resistance element), being a perspective view of the vertical transistor;

FIG. 18 is a diagram for explaining the structure of the vertical transistor formed at the same time with the semiconductor device (N-type variable resistance element), being a plan view of the vertical transistor;

FIG. 19 is a diagram for explaining the structure of the vertical transistor formed at the same time with the semiconductor device (N-type variable resistance element), being a cross-sectional view of the vertical transistor;

FIGS. 20A to 20E are diagrams for showing a step of a manufacturing method of the semiconductor device according to the third embodiment of the invention;

FIGS. 21A to 21B are diagrams for showing a step of the manufacturing method of the semiconductor device according to the third embodiment of the invention;

FIGS. 22A to 22E are diagrams for showing a step of the manufacturing method of the semiconductor device according to the third embodiment of the invention;

FIGS. 23A to 23C are diagrams for showing a step of the manufacturing method of the semiconductor device according to the third embodiment of the invention;

FIGS. 24A to 24C are diagrams for showing a step of the manufacturing method of the semiconductor device according to the third embodiment of the invention;

FIGS. 25A to 25C are diagrams for showing a step of the manufacturing method of the semiconductor device according to the third embodiment of the invention;

FIGS. 26A to 26C are diagrams for showing a step of the manufacturing method of the semiconductor device according to the third embodiment of the invention;

FIGS. 27A to 27B are diagrams for showing a step of the manufacturing method of the semiconductor device according to the third embodiment of the invention;

FIGS. 28A to 28B are diagrams for showing a step of the manufacturing method of the semiconductor device according to the third embodiment of the invention;

FIG. 29 is a plan view for explaining a structure of a semiconductor device (N-type variable resistance element) according to a fourth embodiment of the invention;

FIG. 30 is a diagram for explaining the structure of the semiconductor device (N-type variable resistance element) according to the fourth embodiment of the invention, being a cross-sectional view taken along the dotted line F in FIG. 29;

FIGS. 31A to 31C are diagrams for explaining the structure of the semiconductor device according to the fourth embodiment of the invention, being cross-sectional views taken along the dotted line G in FIG. 29;

FIG. 32 is a plan view for explaining a structure of a semiconductor device according to a fifth embodiment of the invention;

FIG. 33 is a diagram for explaining the structure of the semiconductor device according to the fifth embodiment of the invention, being a cross-sectional view taken along the dotted line H in FIG. 32; and

FIGS. 34A to 34B are diagrams for explaining the structure of the semiconductor device according to the fifth embodiment of the invention, being cross-sectional views taken along the dotted line J in FIG. 32.

### DESCRIPTION OF EXEMPLARY EMBODIMENTS

The present invention will be now described herein with reference to illustrative exemplary embodiments. Those skilled in the art will recognize that many alternative embodiments can be accomplished using the teachings of the present invention and that the invention is not limited to the exemplary embodiments illustrated for explanatory purposes.

### First Exemplary Embodiment

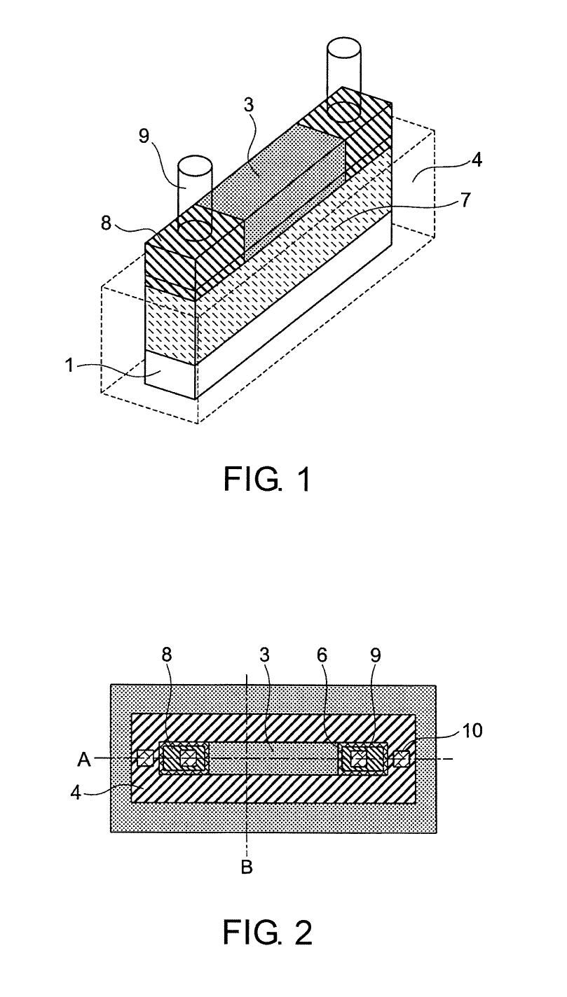

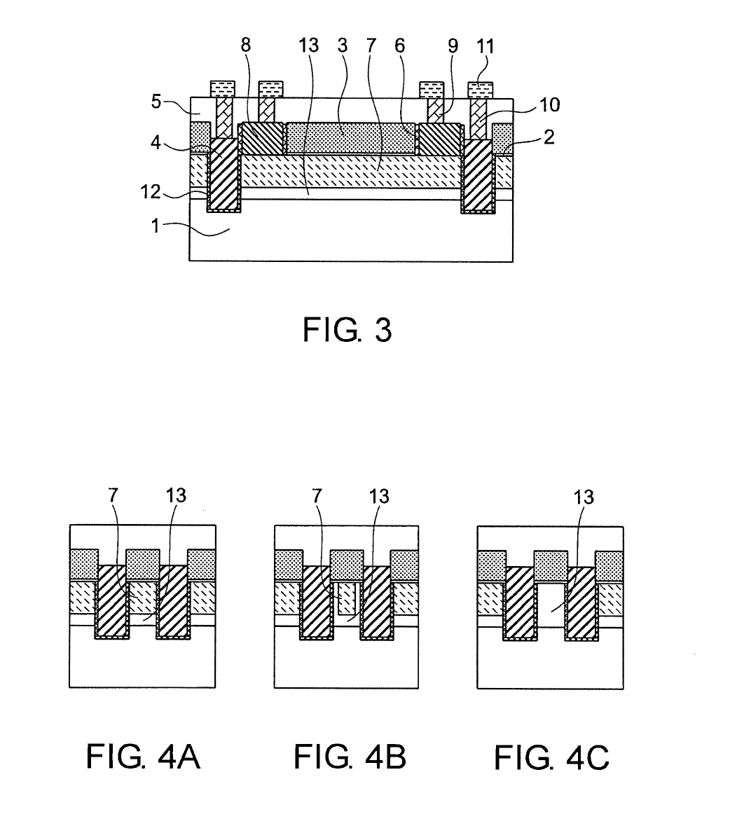

Referring to FIG. 1 to FIG. 4, a structure of a semiconductor device (N-type variable resistance element) according to a first exemplary embodiment of the invention will be described. FIG. 1 is a perspective view of an N-type variable resistance element. FIG. 2 is a plan view showing the N-type variable resistance element as viewed from above with an upper wiring layer and an interlayer oxide film having been removed. A cross sectional view taken along the dotted line A in FIG. 2 is shown in FIG. 3, and cross sectional views taken along the dotted line B in FIG. 2 are shown in FIGS. 4A to 4C.

A silicon substrate 1 is a substrate having a groove in a periphery thereof (silicon beam). A gate electrode 4 is partially embedded in the groove so as to sandwich the silicon substrate 1 from the opposite sides thereof.

An N− diffusion layer 7 is formed on the surface of the silicon substrate 1 between the gate electrodes 4 sandwiching the silicon substrate 1 from the opposite sides thereof. An oxide film 2 is formed on the N− diffusion layer 7. A masking nitride film 3 is formed on the oxide film 2. An N+ diffusion layer 8 is formed on the N− diffusion layer 7. A contact on diffusion layer 9 is formed on the N+ diffusion layer 8. A SW nitride film 6 is formed between the masking nitride film 3 and the N+ diffusion layer 8.

An on-gate contact 10 is formed on the gate electrode 4. An upper wiring layer 11 is formed on the on-gate contact 10. A gate oxide film 12 is formed between the surface of the groove of the silicon substrate 1 and the gate electrode 4. A depletion layer 13 is formed between the silicon substrate 1 and the N− diffusion layer 7.

The N− diffusion layer 7 faces the gate electrode 4 across the gate oxide film 12. Each end of the N− diffusion layer 7 is connected to the upper wiring layer 11 via the N+ diffusion layer 8 and the contact on diffusion layer 9. An interlayer oxide film 5 is formed above the silicon substrate 1.

In the semiconductor device having such a structure, the resistance value of the N− diffusion layer 7 varies as the potential between the gate electrode 4 and the N− diffusion layer 7 is changed. For example, when a negative voltage is applied to the gate electrode 4, the thickness of the depletion layer 13 grows as shown in FIGS. 4A to 4C. As a result of this, the cross-sectional area of the N− diffusion layer 7 can be changed to make the resistance value variable.

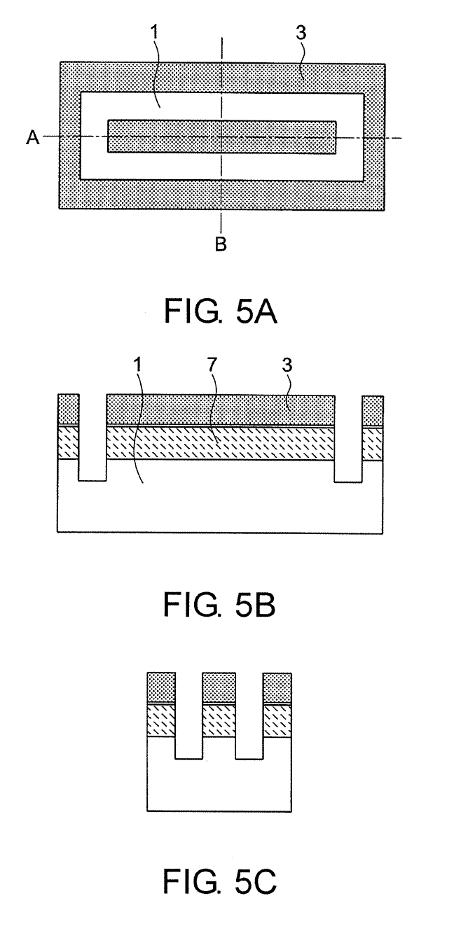

Referring to FIG. 5 to FIG. 9, a manufacturing method of the semiconductor device according to the first exemplary embodiment of the invention will be described.

As shown in FIGS. 5A to 5C, a silicon beam having a groove in a periphery thereof is formed in a silicon substrate 1 having an N− diffusion layer 7 by using a masking nitride film 3 as a mask. The dotted line A in the plan view of FIG. 5A corresponds to the cross-sectional view of FIG. 5B, and the dotted line B corresponds to the cross-sectional view of FIG. 5C.

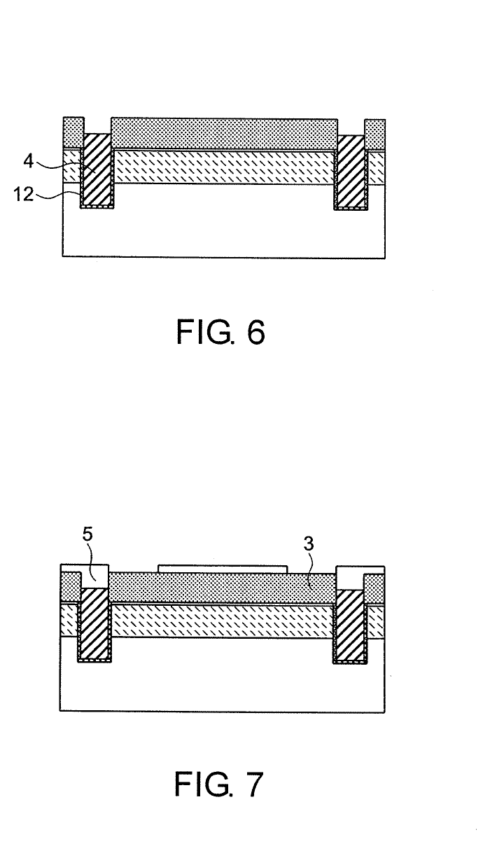

As shown in FIG. 6, a gate oxide film 12 is formed on the surface of the groove of the silicon beam, and then a gate electrode 4 is formed.

Then, as shown in FIG. 7, after an interlayer oxide film 5 is embedded in the groove, the masking nitride film 3 is exposed at the opposite ends of the silicon beam by means of a lithography mask and anisotropic dry etching.

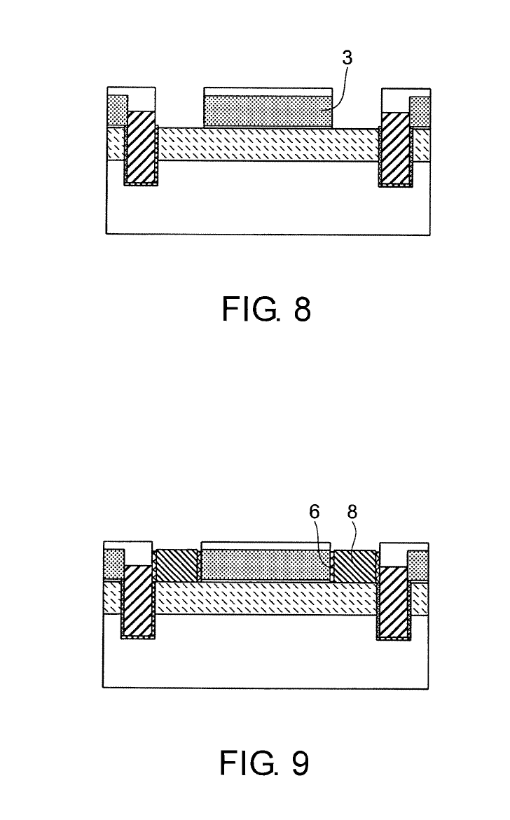

Then, as shown in FIG. 8, the masking nitride film 3 in the exposed portion is removed by anisotropic etching.

Subsequently, as shown in FIG. 9, a SW nitride film 6 is formed and an N+ diffusion layer 8 is formed by means of selective epitaxial growth and ion implantation.

After that, as shown in FIG. 3, the interlayer oxide film 5 is embedded, and the on-gate contact 10 and the upper wiring layer 11 are formed.

In this manner, the semiconductor device according to the first embodiment of the invention (see FIG. 1 to FIG. 3) is completed.

According to the first exemplary embodiment, the N− diffusion layer 7 in the silicon beam is accumulated and depleted by the gate electrode 4 to make the resistance variable, so that the resistance value can be made controllable after fabrication of the chip.

### Second Exemplary Embodiment

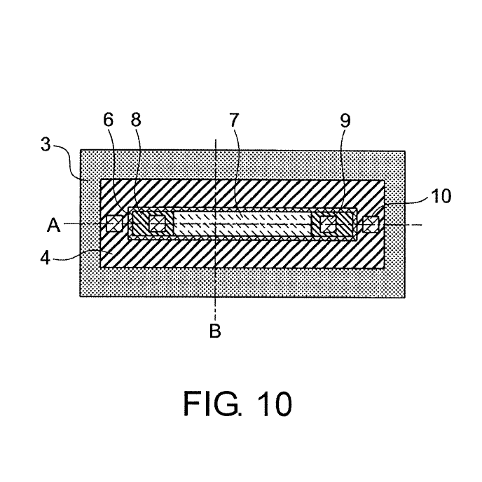

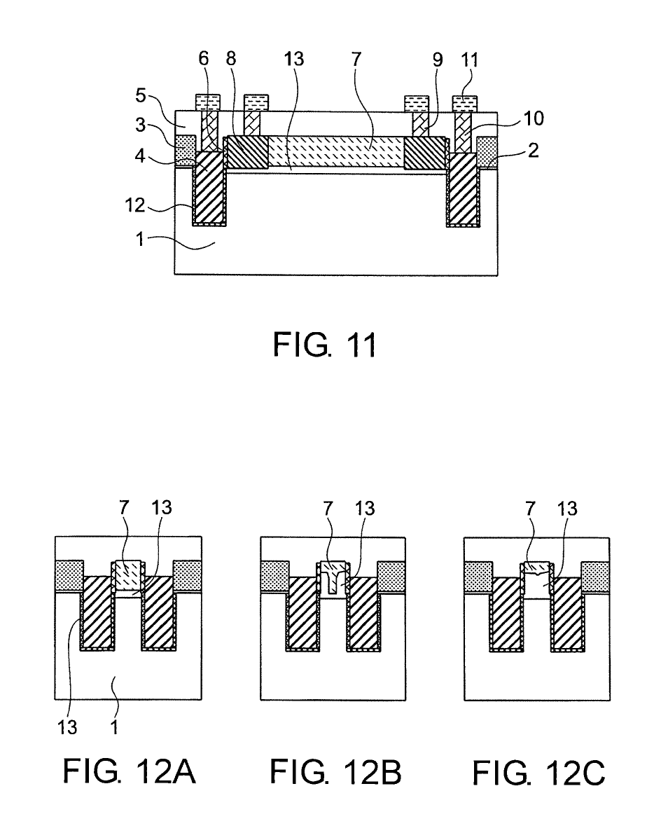

Next, referring to FIG. 10 to FIG. 12, a structure of a semiconductor device (N-type variable resistance element) according to a second exemplary embodiment of the invention will be described. FIG. 10 is a plan view, and the cross-sectional view taken along the dotted line A in FIG. 10 is shown in FIG. 11 and the cross-sectional views taken along the dotted line B in FIG. 10 are shown in FIGS. 12A to 12C. FIG. 10 shows a view as viewed from above with an upper wiring layer and interlayer oxide film having been removed.

The structure according to the second exemplary embodiment of the invention is the same as that of the first embodiment of the invention except that epitaxial silicon is used as the N− diffusion layer 7 on the silicon substrate 1, and hence detailed description thereof will be omitted.

As shown in FIG. 10 and FIG. 11, an N− diffusion layer 7 formed by selective epitaxial growth is provided above the silicon substrate 1.

In the second embodiment as well, like the first exemplary embodiment, as shown in FIGS. 12A to 12C, the resistance value of the N− diffusion layer 7 varies as the potential between a gate electrode 4 and the N− diffusion layer 7 is changed. When a negative voltage is applied to the gate electrode 4, for example, the thickness of a depletion layer 13 grows as shown in FIGS. 12A to 12C. As a result of this, the cross-sectional area of the N− diffusion layer 7 can be changed to make the resistance value variable.

Although not shown in the drawings, it is also possible to form a variable N− diffusion layer resistance by arranging polysilicon on the STI of a similar structure.

According to the second exemplary embodiment, the N− diffusion layer 7 in the silicon beam is accumulated and depleted by the gate electrode 4 to make the resistance variable, so that the resistance value can be made controllable after fabrication of the chip.

### Third Exemplary Embodiment

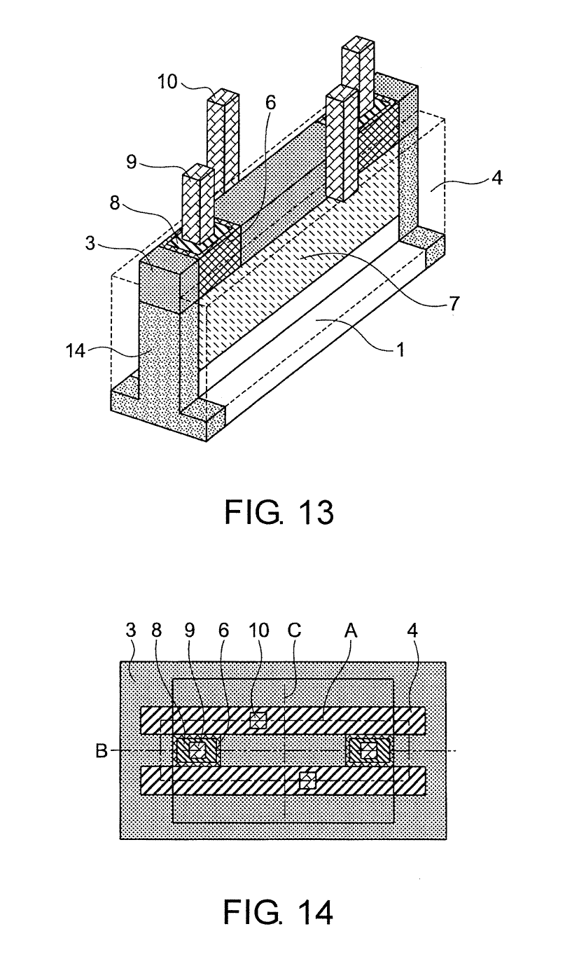

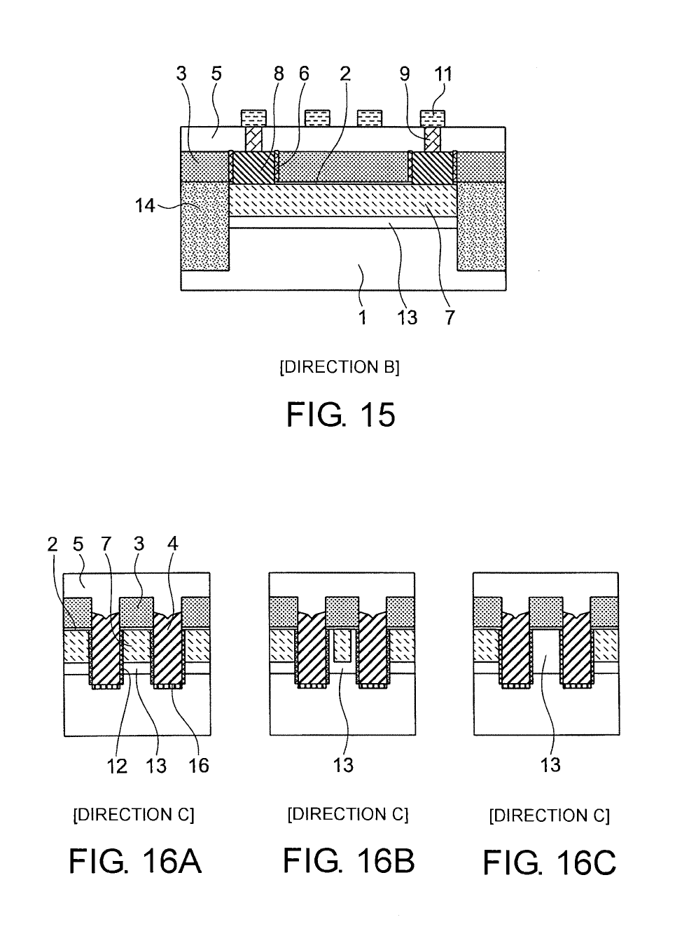

Referring to FIG. 13 to FIG. 19, a structure of a semiconductor device (N-type variable resistance element) according to a third exemplary embodiment of this invention will be described. FIG. 13 is a perspective view of the N-type variable resistance element, and corresponds to a range enclosed by the dotted line A in FIG. 14. In FIG. 13, a gate electrode 4 is illustrated by the dotted lines. FIG. 14 is a plan view as viewed from above with an upper wiring layer and an interlayer oxide film having been removed. A cross-sectional view taken along the dotted line B in FIG. 14 is shown in FIG. 15, and cross-sectional views taken along the dotted line C in FIG. 14 are shown in FIGS. 16A to 16C. Like components as those in FIG. 1 to FIG. 4 showing the first exemplary embodiment are assigned with like reference numerals.

The semiconductor device according to the third exemplary embodiment is different from the semiconductor device according to the first exemplary embodiment in that a STI 14 is provided in the periphery and a masking nitride film 3 is formed on the STI 14, and that a pair of gate electrodes 4 are provided to face each other. The other details of the structure are substantially the same as those of the semiconductor device according to the first exemplary embodiment (see FIG. 1 to FIG. 3), and hence description thereof will be omitted here.

In the third exemplary embodiment as well, like the first exemplary embodiment, as shown in FIGS. 16A to 16C, the resistance value of the N− diffusion layer 7 varies as the potential between the gate electrode 4 and the N− diffusion layer 7 is changed. When a negative voltage is applied to the gate electrode 4, for example, the thickness of the depletion layer 13 grows as shown in FIG. 16A to FIG. 16C. As a result of this, the cross-sectional area of the N− diffusion layer 7 can be changed to make the resistance value variable. Further, different potentials can be applied to the respective gate electrodes 4 at the opposite ends of the silicon beam, which enables precise control the resistance value.

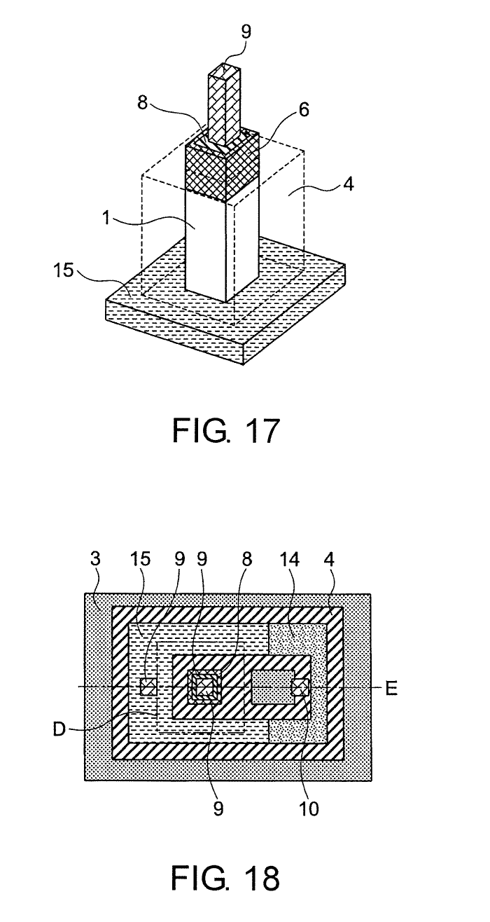

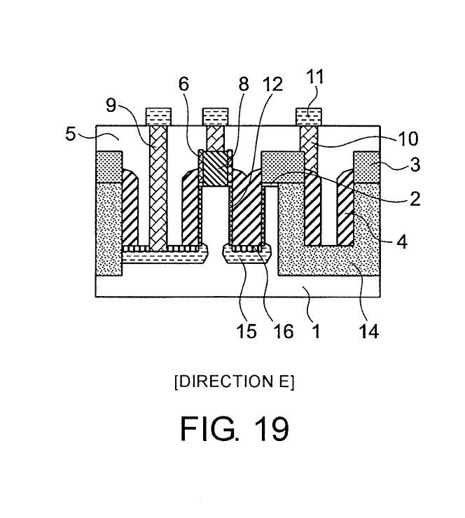

Next, referring to FIG. 17 to FIG. 19, a structure of a vertical transistor formed at the same time with the semiconductor device (N-type variable resistance element) will be described. FIG. 17 is a perspective view showing the vertical transistor and corresponds to the range enclosed by the dotted lines D in the plan view of FIG. 18. The direction E in the plan view of FIG. 18 corresponds to FIG. 19. Like components as those in FIG. 1 to FIG. 4 illustrating the first exemplary embodiment are assigned with like reference numerals. FIG. 19 shows the structure including an interlayer oxide film and an upper wiring layer which are formed in later steps.

An N+ diffusion layer (lower part) 15 is formed on the silicon substrate 1, and a gate electrode 4 is formed on the N+ diffusion layer (lower part) 15 via a gate oxide film 12 and a lower oxide film 16. The N+ diffusion layer (lower part) 15 is connected to an upper wiring layer 11 via a contact on diffusion layer 9.

A trench-shaped STI 14 is formed on the silicon substrate 1 and a gate electrode 4 is formed in the inside of the STI 14. A masking nitride film 3 is provided on the STI 14. The gate electrode 4 is connected to the upper wiring layer 11 via the on-gate contact 10. The N+ diffusion layer (upper part) is connected to the upper wiring layer 11 via the contact.

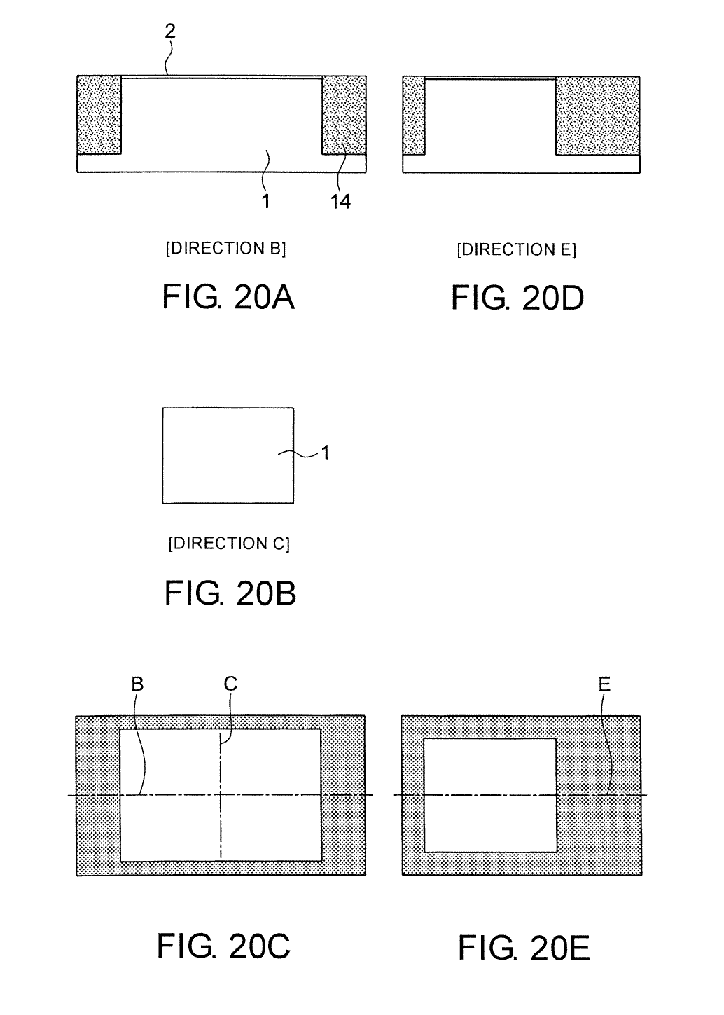

Next, referring to FIG. 20 to FIG. 28, a manufacturing method of the semiconductor device according to the third exemplary embodiment of this invention will be described. This manufacturing method relates to a manufacturing method of an N-type variable resistance element and a vertical transistor. Cross-sectional views of the direction B and direction C show cross-sections of the N-type variable resistance element, whereas a cross-sectional view of the direction E shows a cross-section of the vertical transistor. The plan view is a view as viewed through the oxide film.

FIGS. 20A to 20E illustrate respective steps of fabricating the STI 14 to a depth of 300 nm

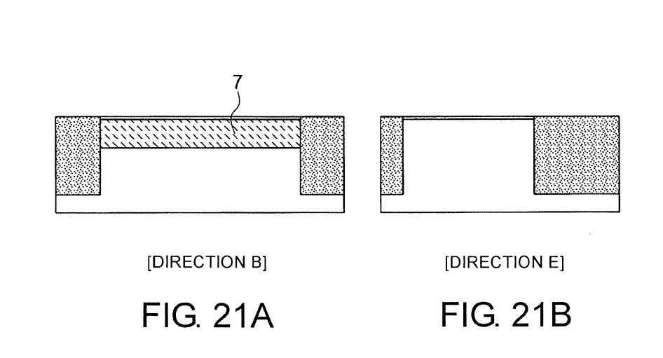

As shown in FIG. 21A, an N− diffusion layer 7 is formed by ion implantation. During this process, as shown in FIG. 21B, the region of the vertical transistor is masked with photoresist (not shown) so that no N− diffusion layer 7 is formed in this region.

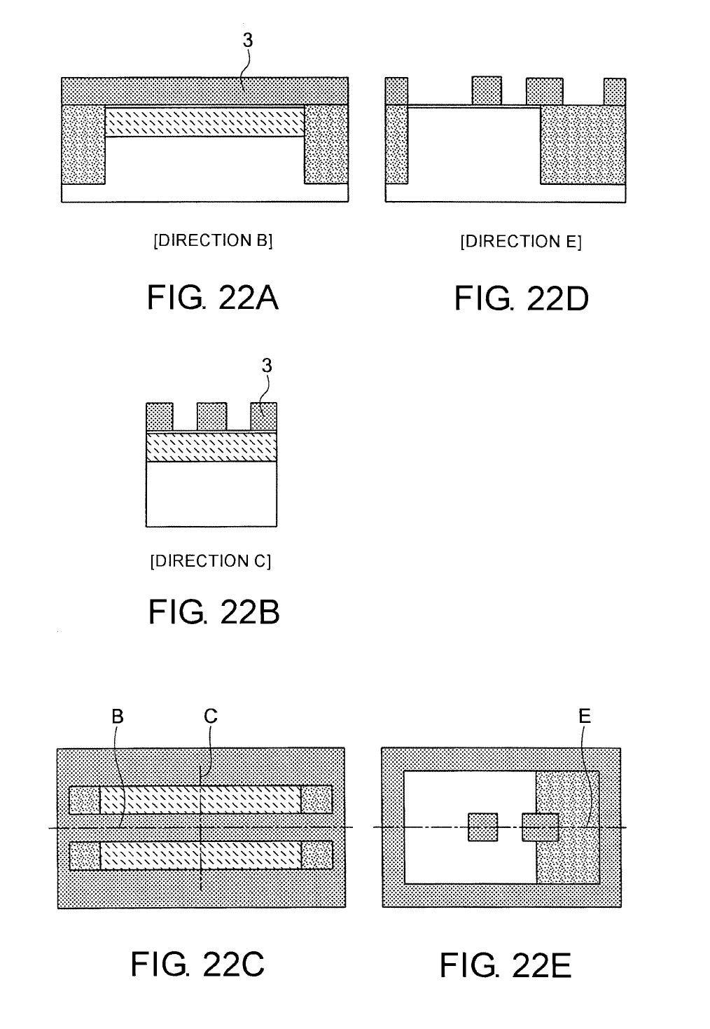

Next, as shown in FIGS. 22A to 22E, a masking nitride film 3 for forming a pillar pattern is formed by PEP (Photo Etching Process). The masking nitride film 3 has a thickness of about 100 nm.

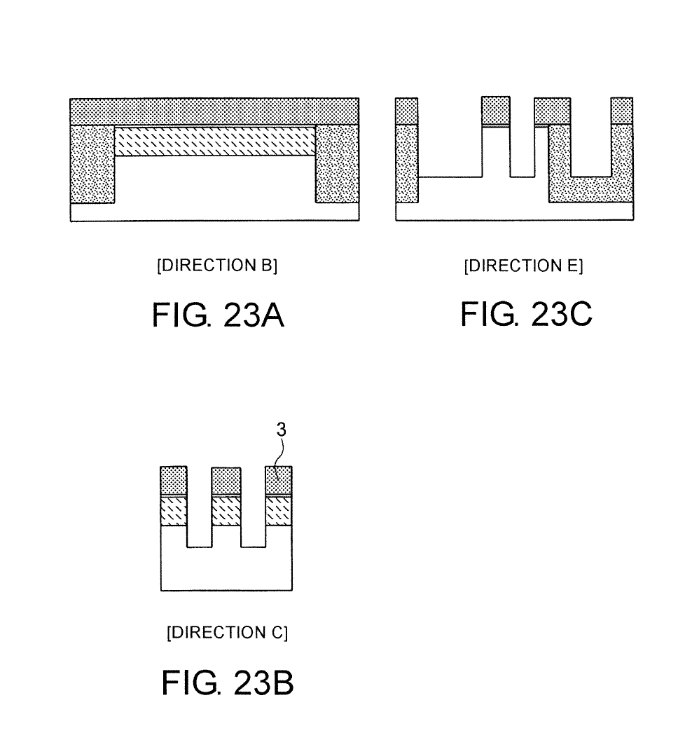

As shown in FIGS. 23A to 23C, anisotropic dry etching is performed with the masking nitride film 3 used as an etching mask to a depth of 150 nm, whereby a pillar pattern is formed.

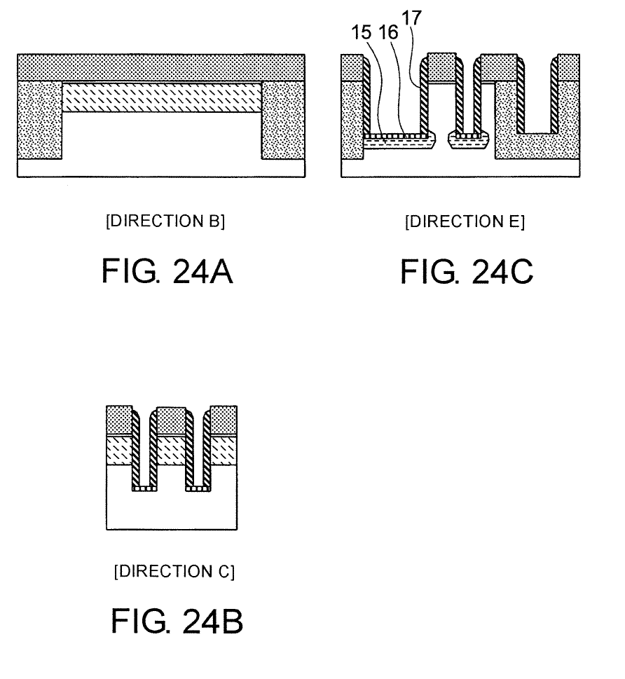

As shown in FIGS. 24A to 24C, a pillar SW nitride film 17 is formed by LP-CVD (Low Pressure Chemical Vapor Deposition) and anisotropic dry etchback process to a thickness of about 15 nm, then a lower oxide film 16 is formed by thermal oxidation to a thickness of about 10 nm, and a N+ diffusion layer 15 is formed by ion implantation.

During this process, the pillar SW nitride film 17 protects the N− diffusion layer 14 of the N-type variable resistance element and the channel portion of the vertical transistor from the oxidation and ion implantation. The N-type variable resistance element region is masked with photoresist so that no N+ diffusion layer 15 is formed in this region.

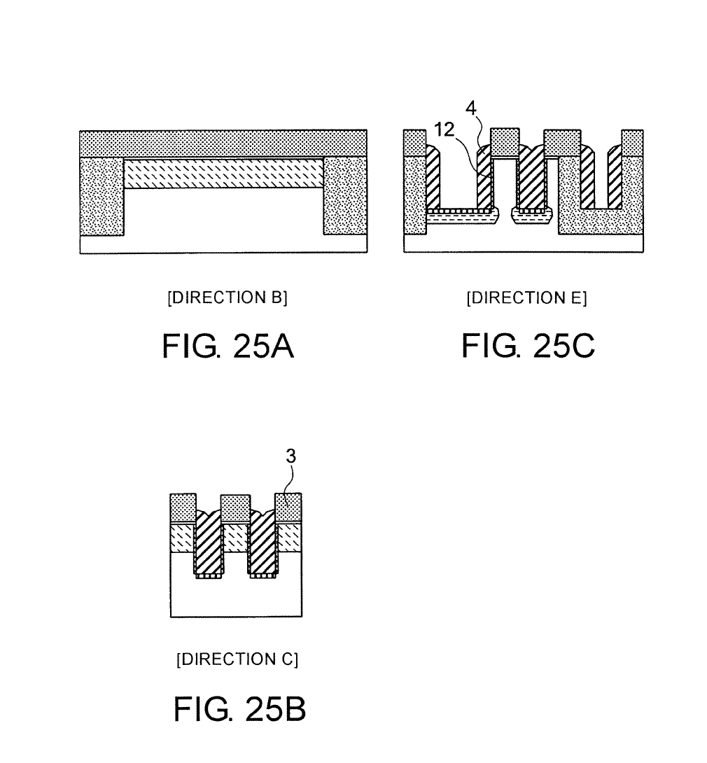

Then, as shown in FIGS. 25A to 25C, after the pillar SW nitride film 17 is removed with thermal phosphate, a gate oxide film 12 is formed by thermal oxidation to a thickness of about 3 nm, and then a gate electrode 4 is formed to a thickness of 40 nm. The gate electrode 4 is formed by performing anisotropic etchback process after depositing polysilicon all over the surface by LP-CVD.

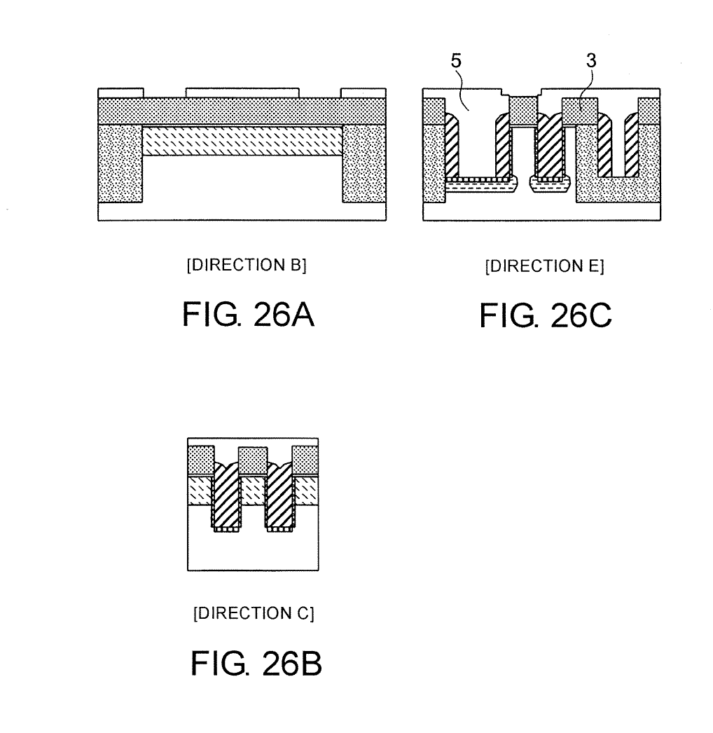

Subsequently, as shown in FIGS. 26A to 26C, an interlayer oxide film 5 is formed. The formation of the interlayer oxide film 5 is performed by first embedding an oxide film by HDP (High Density Plasma), and then performing CMP (Chemical Mechanical Polishing) with the masking nitride film 3 used as a stopping film. After that, a thin oxide film is formed, and then only the oxide film located above a region where an upper diffusion layer is to be formed is removed by way of a lithography process and an etching process, whereby the masking nitride film 3 is exposed.

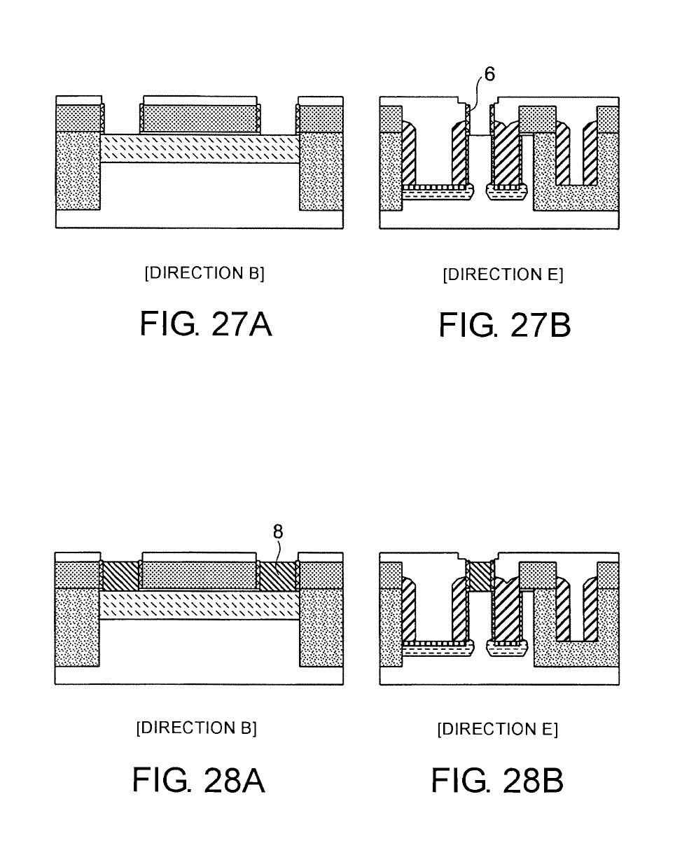

As shown in FIG. 27A and FIG. 27B, after the exposed nitride film is removed by anisotropic dry etching and thermal phosphate, a SW nitride film 6 is formed to a thickness of 15 nm by LP-CVD and anisotropic dry etching.

As shown in FIGS. 28A and 28B, an upper diffusion layer 8 is formed by selective epitaxial growth and ion implantation. Then, as shown in FIGS. 15 and 19, an interlayer oxide film 5 is embedded, and a contact on diffusion layer 9, an on-gate contact 10 and an upper wiring layer 11 are formed.

In this manner, the semiconductor device according to the third exemplary embodiment of this invention is completed.

According to the third exemplary embodiment, the N-type variable resistance element as shown in FIG. 15 can be fabricated at the same time with the vertical transistor shown in FIG. 17 and yet without substantial increase in number of manufacturing steps.

### Fourth Exemplary Embodiment

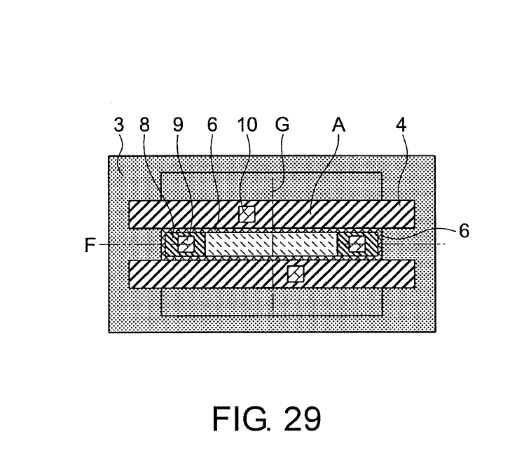

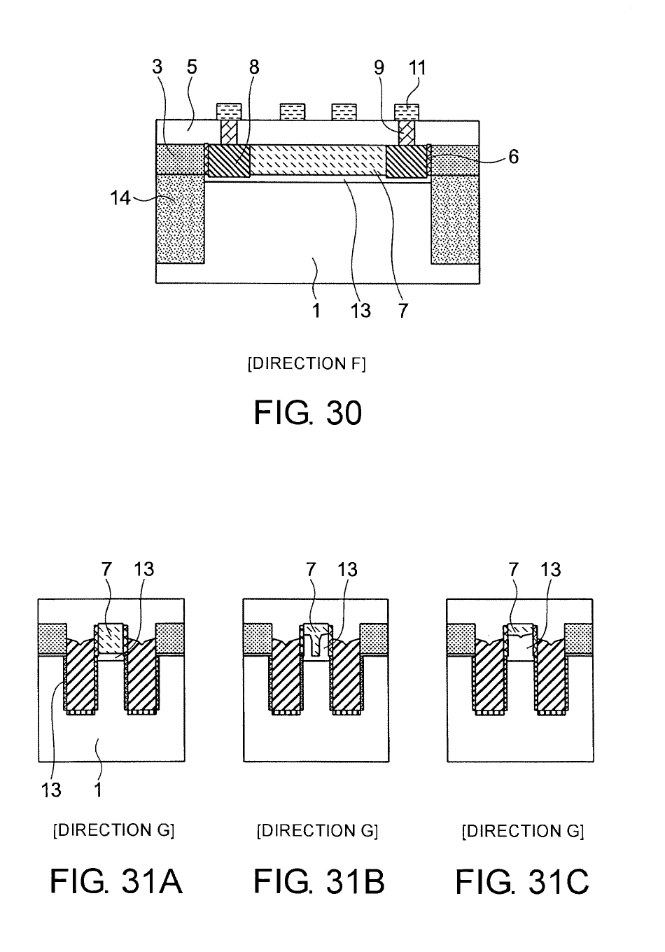

Next, referring to FIG. 29 to FIG. 31, a structure of a semiconductor device (N-type variable resistance element) according to a fourth exemplary embodiment of this invention will be described. FIG. 29 is a plan view. A cross section taken along the dotted line F in FIG. 29 is shown in FIG. 30 and cross sections taken along the dotted line G in FIG. 29 are shown in FIGS. 31A to 31C. FIG. 29 shows a view as viewed from above with an upper wiring layer and an interlayer oxide film having been removed.

The structure of the fourth exemplary embodiment of the invention is the same as that of the third exemplary embodiment of the invention except that epitaxial silicon is used as an N− diffusion layer 7 on a silicon substrate 1, and hence detailed description thereof will be omitted.

As shown in FIG. 29 and FIG. 30, an N− diffusion layer 7 formed by selective epitaxial growth is arranged in an upper part of the silicon substrate 1.

Like the third exemplary embodiment, in the fourth exemplary embodiment as well, as shown in FIG. 31A to FIG. 31C, the resistance value of the N− diffusion layer 7 varies as the potential between the gate electrode 4 and the N− diffusion layer 7 is changed. For example, when a negative voltage is applied to the gate electrode 4, the thickness of a depletion layer 13 grows as shown in FIG. 31A to FIG. 31C. As a result of this, the cross-sectional area of the N− diffusion layer 7 can be changed to make the resistance value variable.

Although not shown in the drawings, it is also possible to form a variable N− diffusion layer resistance by arranging polysilicon on the STI of a similar structure.

According to the fourth exemplary embodiment, like the third exemplary embodiment, an N-type variable resistance element can be fabricated at the same time with a vertical transistor without substantial increase in the number of manufacturing steps.

### Fifth Exemplary Embodiment

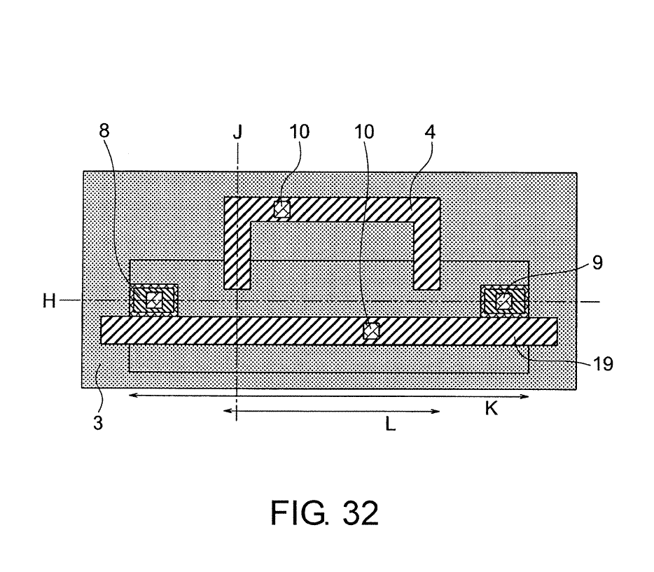

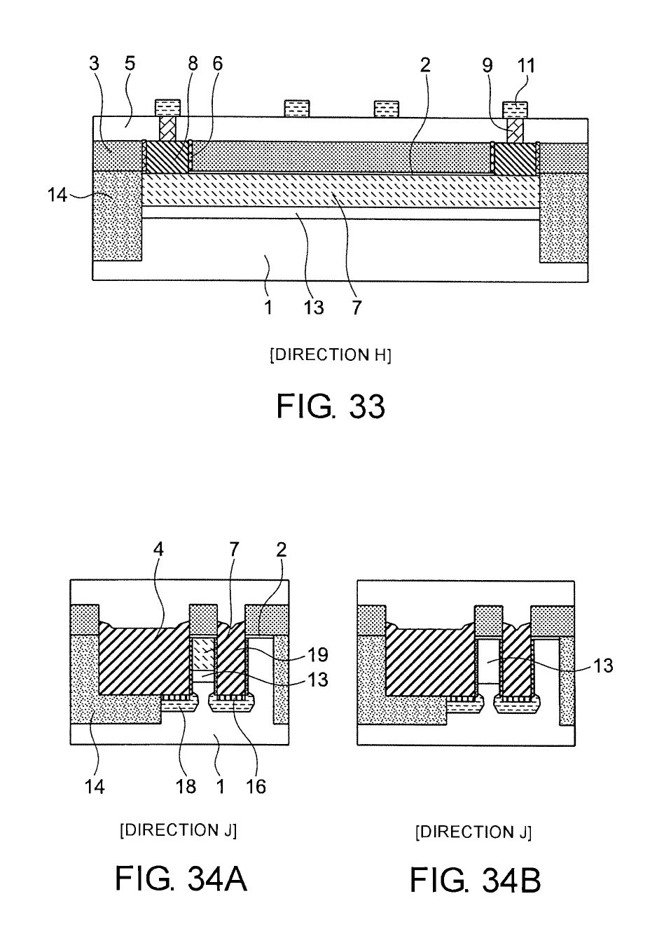

Next, referring to FIGS. 32 to 34, a structure of a semiconductor device according to a fifth exemplary embodiment of this invention will be described. FIG. 32 illustrates a structure of the semiconductor device including an interlayer oxide film which is to be formed in a later step. FIG. 33 also illustrates a structure of the semiconductor device including an interlayer oxide film and an upper wiring layer which are to be formed in later steps.

FIGS. 32 to 34 illustrate an example in which a variable capacity element is fabricated by using an N− diffusion layer in a silicon substrate 1 as a capacity electrode. A cross section taken along the dotted line H in the plan view of FIG. 32 corresponds to FIG. 33, and a cross section taken along the dotted line J corresponds to FIG. 34.

A capacity value between a capacity electrode 19 and another capacity electrode of N− diffusion layer 7 is controlled with a gate electrode 4. Specifically, a case is considered in which a positive voltage is applied to the capacity electrode 19 with the N− diffusion layer 7 set to GND. When a positive voltage is applied to the gate electrode 4, the N− diffusion layer 7 as shown in FIG. 34A that is a cross section in the direction J remains without change, and therefore the capacity value is a value defined by a width K in FIG. 32.

When a negative voltage is applied to the gate electrode 4, the N− diffusion layer 7 is deplete as shown in FIG. 34B that is a cross section in the direction J, and therefore a component of a width L in FIG. 32 is lost and the capacity value becomes a value defined by K−L.

In this manner, the variable capacity element according to the fifth exemplary embodiment is able to have two different capacity values. Like the third exemplary embodiment, this variable capacity element also can be fabricated at the same time with the vertical transistor without substantial increase in the number of manufacturing steps.

According the exemplary embodiments of this invention, variation in resistance value caused by processing variation can be prevented in a semiconductor device which has a silicon beam used therein and has a double-gate structure.

Although the invention made by the present inventor has been described based on several preferred exemplary embodiments, it should be understood that this invention is not limited to the exemplary embodiments but various modifications and changes are possible without departing from the spirit and scope of the invention.

What is claimed is:

1. A semiconductor device, comprising:
a substrate having a groove in a periphery;
a gate electrode partially embedded in the groove to sandwich the substrate from opposite directions by side walls of the groove; and
a diffusion layer formed over the substrate and surrounded by the gate electrode;
wherein a resistance value of the diffusion layer is changed by changing a potential between the gate electrode and the diffusion layer.

2. The semiconductor device according to claim 1, wherein the resistance value of the diffusion layer is changed depending upon a cross-sectional area of the diffusion layer, the cross-sectional area being changed in accordance with a thickness of a depletion layer formed between the substrate and the diffusion layer.

3. The semiconductor device according to claim 2, wherein the gate electrode is formed by two gate electrodes facing each other.

4. The semiconductor device according to claim 2, wherein the gate electrode is formed to surround a periphery of the diffusion layer.

5. The semiconductor device according to claim 2, wherein the diffusion layer is an epitaxial silicon layer.

6. The semiconductor device according to claim 2, wherein the diffusion layer is a polysilicon layer.

7. The semiconductor device according to claim 3, wherein different potentials are applied to the two gate electrodes, respectively.

8. The semiconductor device according to claim 3, wherein a variable capacity element is formed by using the diffusion layer as a capacity electrode, and controlling a capacity value between the capacity electrode and the diffusion layer by the gate electrode.

9. The semiconductor device according to claim 8, wherein the variable capacity element has a first capacity value when a positive voltage is applied to the gate electrode, and has a second capacity value when a negative voltage is applied to the gate electrode, in case where the diffusion layer is set to GND and a positive voltage is applied to the capacity electrode.

10. The semiconductor device according to claim 9, wherein the second capacity value is determined by a width in a gate extension direction of the diffusion layer which is sandwiched between the capacity electrode and the gate electrode.

11. The semiconductor device according to claim 2, wherein the semiconductor device is provided together with a vertical transistor.

12. A semiconductor device, comprising:
a substrate having a groove in a periphery;
a gate electrode partially embedded in the groove to sandwich the substrate from opposite directions by side walls of the groove; and
a diffusion layer formed over the substrate and surrounded by the gate electrode;
wherein:
a resistance value of the diffusion layer is changed by changing a potential between the gate electrode and the diffusion layer,
the resistance value of the diffusion layer is changed depending upon a cross-sectional area of the diffusion layer, the cross-sectional area being changed in accordance with a thickness of a depletion layer formed between the substrate and the diffusion layer, and
the semiconductor device is provided together with a vertical transistor.

13. The semiconductor device according to claim 12, wherein the gate electrode is formed by two gate electrodes facing each other, and different potentials are applied to the two gate electrodes, respectively.

14. The semiconductor device according to claim 12, wherein the gate electrode is formed to surround a periphery of the diffusion layer.

15. The semiconductor device according to claim 12, wherein the diffusion layer is an epitaxial silicon layer.

16. The semiconductor device according to claim 12, wherein the diffusion layer is a polysilicon layer.

17. The semiconductor device according to claim 13, wherein:
a variable capacity element is formed by using the diffusion layer as a capacity electrode, and controlling the capacity value between the capacity electrode and the diffusion layer by the gate electrode,
the variable capacity element has a first capacity value when a positive voltage is applied to the gate electrode, and has a second capacity value when a negative voltage is applied to the gate electrode, in case where the diffusion layer is set to GND and a positive voltage is applied to the capacity electrode, and
the second capacity value is determined by a width in a gate extension direction of the diffusion layer which is sandwiched between the capacity electrode and the gate electrode.

18. A semiconductor device, comprising:
a semiconductor substrate including a groove which is defined by a first side surface, a second side surface, a third side surface, and a fourth side surface, the first and second side surface being faced to each other, the third and fourth side surface being faced to each other;
a gate electrode formed in the groove and having a first portion to be in contact with the first side surface and a second portion to be in contact with second side surface;
a slit provided between the first and second portions of the gate electrode;
a first diffusion layer formed in the slit and including a first end portion and a second end portion;
a second diffusion layer formed on the first end portion of the first diffusion layer;
a third diffusion layer formed on the second end portion of the first diffusion layer;
a first plug contact formed on the second diffusion layer; and
a second plug contact formed on the third diffusion layer.

19. The semiconductor device according to claim 18, further comprising:
a semiconductor device having a vertical transistor.

20. The semiconductor device according to claim 18, wherein the second diffusion layer is between the first end portion of the first diffusion layer and the first portion of the gate electrodes, and
the third diffusion layer is between the second end portion of the first diffusion layer and the second portion of the gate electrodes.
